(19) United States
(12) Patent Application Publication
(10) Pub. No.: US 2016/0155618 A1
(43) Pub. Date: Jun. 2, 2016

(54) VACUUM ION SPUTTERING TARGET DEVICE

(71) Applicant: SHENZHEN CHINA STAR OPTOELECTRONICS TECHNOLOGY CO., LTD., Guangdong (CN)

(72) Inventor: Tao Zhou, Guangdong (CN)

(21) Appl. No.: 14/416,150

(22) PCT Filed: Dec. 8, 2014
(86) PCT No.: PCT/CN2014/093214

§ 371 Date: Jan. 21, 2015

(30) Foreign Application Priority Data
Dec. 2, 2014 (CN) 201410720262.5

(51) Int. Cl. H01J 37/34

(52) U.S. Cl. CPC H01J 37/3423; H01J 37/3405; H01J 37/3426

(57) ABSTRACT

A vacuum ion sputtering target device is disclosed, which has an accommodating space provided with a substrate, a magnetron, a target, and a back plate disposed therein. The target is disposed above the back plate, the magnetron is provided below the back plate, the substrate is disposed above the target; wherein a shape of the target depends on a distribution of a magnetic field strength. Target utilization is quiet high, and there is basically no target remaining, so costs will be reduced.

### FIELD OF THE INVENTION

The present invention relates to the technical field of vacuum ion sputtering, and in particular to a vacuum ion sputtering target device.

### BACKGROUND OF THE INVENTION

In the conventional art, the operating principle of the vacuum sputtering is as follows: glow discharge is used to make argon (Ar) ions hit the target surface, and the atoms of the target are ejected to accumulate on the surface of the substrate to form a thin film. A sputtered thin film has better properties and uniformity than a deposited thin film, but the sputtering rate of the sputtered thin film is much slower than that of the deposited thin film. Generally, DC sputtering is adopted for metal plating, and RF sputtering is adopted for non-conductive ceramic material. The basic principle is to make the argon ions hit the target surface by initiating the glow discharge. Positive ions of the plasma are accelerated toward a negative electrode surface which is configured as a sputtering material, so as the motion will carry the target substance and deposit it on the substrate to form the thin film.

Currently, the target shape used in vacuum sputtering is usually rectangular. New sputtering equipment uses strong magnets to move the electrons in a spiral shape so as to accelerate argon ionization around the target, resulting in increasing collision probability between the target and the argon ions, and also improving the sputtering rate. Therefore, the target surface hit by the ions forms a wavy shape, and leads to a very low target utilization, generally only about 15%, resulting in a very large waste.

As shown in FIG. 1, the target used in vacuum sputtering is a rectangular shape and the target surface hit by the ions will form a wavy shape, i.e. the shadow portion in FIG. 1 is the consumed portion 10 of the target, so that the remaining portion of the target is large, i.e. the blank portion in FIG. 1 is the remaining portion 20 of the target. This can be seen from the figure. The rectangular target will result in a very large waste and then cause low utilization of the target material. As another example, when a part of the remaining target approaches a copper back plate, i.e. the black portion 30 is the copper back plate, and the other part of the remaining target is large, the target still needs to be scrapped, and needs to be exchanged with a new rectangular target to continue the vacuum sputtering operation, thereby causing a very large waste and a low target utilization.

Accordingly, it is necessary to provide a new technical solution to solve the above problems.

### SUMMARY OF THE INVENTION

The object of the present invention is to provide a vacuum ion sputtering target device which can solve a low target utilization in the conventional art caused by adopting a rectangular shaped target as a target material.

In order to solve the above problem, the technical solution of the present invention is as follows:

A vacuum ion sputtering target device, comprising: an accommodating space provided with a substrate, a magnetron, a target, and a back plate therein, the target is disposed above the back plate, the magnetron is provided below the back plate, and the substrate is disposed above the target; wherein a shape of the target depends on a distribution of a magnetic field strength; wherein the target has a greater thickness in a region corresponding to a higher magnetic field strength, the target has a smaller thickness in a region corresponding to a lower magnetic field strength; the target is an integrally molded structure; wherein during a vacuum sputtering process, the magnetron generates a magnetic field between the target and the substrate, when the accommodating space is provided with plasma, the plasma accelerated in the electric field hits the target, and sputters a large number of target atoms; the target atoms are deposited on the substrate to form a thin film.

Preferably, when the distribution of the magnetic field strength shows a wavy shape, a lower surface of the target shows the wavy shape, an upper surface of the back plate shows the wavy shape; a peak at the lower surface of the target matches to a valley at the upper surface of the back plate, so that the target and the back plate are closely combined.

Preferably, the lower surface of the target shows a wavy shape having two peaks, and the upper surface of the back plate shows a wavy shape having two valleys; the two peaks at the lower surface of the target are embedded in the two valleys at the upper surface of the back plate, so that the target and the back plate are closely combined.

Preferably, the upper surface of the target is a flat plane.

Preferably, the wavy shape at the lower surface of the target is symmetrically disposed.

Preferably, the thickness and a size of the target depend on actual consumption.

Preferably, the target is a metal target, including: titanium target (Ti), aluminum target (Al), stannum target (Sn), hafnium target (Hf), lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), or germanium target (Ge).

Preferably, the target is an alloy target, including: iron-cobalt target (FeCo), aluminum-silicon target (AlSi), titanium-silicon target (TiSi), chrome-silicon target (CrSi), zinc-aluminum target (ZnAl), titanium-zinc target (TiZa), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), or nickel-iron target (NiFe).

A vacuum ion sputtering target device, comprising: an accommodating space provided with a substrate, a magnetron, a target, and a back plate therein, the target is disposed above the back plate, the magnetron is provided below the back plate, and the substrate is disposed above the target; wherein a shape of the target shape depends on a distribution of a magnetic field strength; wherein during a vacuum sputtering process, the magnetron generates a magnetic field between the target and the substrate, when the accommodating space is provided with plasma, the plasma accelerated in the electric field hits the target, and sputters a large number of target atoms, the target atoms are deposited on the substrate to form a thin film.

Preferably, the target has a greater thickness in a region corresponding to a higher magnetic field strength, the target has a smaller thickness in a region corresponding to a lower magnetic field strength.

Preferably, when the distribution of the magnetic field strength shows a wavy shape, a lower surface of the target shows the wavy shape, an upper surface of the back plate shows the wavy shape; a peak at the lower surface of the target matches to a valley at the upper surface of the back plate, so that the target and the back plate are closely combined.

Preferably, the lower surface of the target shows a wavy shape having two peaks, and the upper surface of the back plate shows a wavy shape having two valleys; the two peaks at the lower surface of the target are embedded in the two valleys at the upper surface of the back plate, so that the target and the back plate are closely combined.

Preferably, an upper surface of the target is a flat plane.

Preferably, the wavy shape at the lower surface of the target is symmetrically disposed.

Preferably, the thickness and a size of the target depend on actual consumption.

Preferably, the target is a metal target, including: titanium target (Ti), aluminum target (Al), stannum target (Sn), hafnium target (Hf), lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), or germanium target (Ge).

Preferably, the target is an alloy target, including: iron-cobalt target (FeCo), aluminum-silicon target (AlSi), titanium-silicon target (TiSi), chrome-silicon target (CrSi), zinc-aluminum target (ZnAl), titanium-zinc target (TiZn), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), or nickel-iron target (NiFe).

Preferably, the target is an integrally molded structure.

Compared with the conventional art, the shape of the target provided by the present invention depends on the distribution of the magnetic field strength. For example, the target is made into a wavy shape, such as a W-shape. Since in the vacuum sputtering process the wavy shape is formed on the target surface hit by the plasma, i.e. the consumed target has the wavy shape, the shape of the target is made into the wavy shape so the target can be used efficiently. Basically, there is no target remaining so that costs can be reduced. The target having the wavy shape provided the present invention can efficiently prevent the low target utilization problem which occurs in the conventional art conventional caused by adopting the rectangular target as a sputtering material.

For a better understanding of the aforementioned content of the present invention, preferable embodiments are illustrated in accordance with the attached figures.

### BRIEF DESCRIPTION OF THE DRAWINGS

FIG. 1 is a schematic diagram of a target after sputtering in a conventional art;

FIG. 1A is a schematic diagram of a vacuum ion sputtering target device provided in one embodiment of the present invention;

FIG. 2 is a schematic diagram of a target structure provided in the first embodiment of the present invention;

FIG. 3 is a schematic diagram of a target structure before sputtering provided in the first embodiment of the present invention;

FIG. 4 is a schematic diagram of a target structure after sputtering provided in the first embodiment of the present invention;

FIG. 5 is a schematic diagram of a target structure provided in the second embodiment of the present invention;

FIG. 6 is a schematic diagram of a target structure before sputtering provided in the second embodiment of the present invention; and

FIG. 7 is a schematic diagram of a target structure after sputtering provided in the second embodiment of the present invention.

### DETAILED DESCRIPTION OF THE PREFERRED EMBODIMENTS

As used herein, the word “exemplary” is used to mean serving as an example, instance, or illustration. In addition, the articles “a” and “an” as used in this application and the appended claims should generally be, construed to mean “one or more” unless specified otherwise or clear from context to be directed to a singular form.

In the present invention, the shape of the target provided depends on a distribution of a magnetic field strength. For example, the target is made into a wavy shape, such as W-shape. Since in the vacuum sputtering process the wavy shape is formed on the target surface hit by the plasma, i.e. the consumed target has the wavy shape, the shape of the target is made into the wavy shape so the target can be used efficiently. Basically, there is no remaining target so that costs can be reduced. The target having the wavy shape provided by the present invention can efficiently solve the low target utilization problem which occurs in the conventional art caused by adopting the rectangular target as a sputtering material.

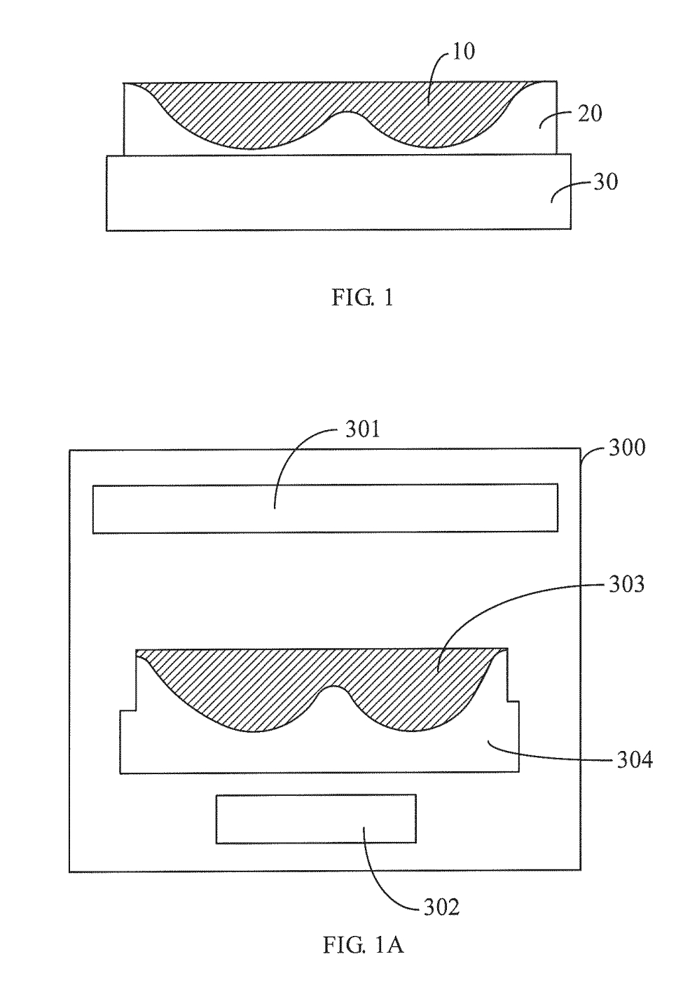

Please refer to FIG. 1A which is the schematic diagram of a vacuum ion sputtering target device provided by one embodiment of the present invention. In order to explain the instant embodiment conveniently, only a relative part to the present embodiment is illustrated herein. The present invention provides a vacuum ion sputtering target device, and the vacuum ion sputtering target device comprises an accommodating space 300 provided with a substrate 301, a magnetron 302, a target 303, and a back plate 304 disposed therein, the target 303 is disposed above the back plate 304, the magnetron 302 is provided below the back plate 304, and the substrate 301 is disposed above the target 303; wherein a shape of the target 303 depends on a distribution of a magnetic field strength.

In a vacuum sputtering process, the magnetron 302 generates a magnetic field between the target 303 and the substrate 302, when the accommodating space 300 is provided with a plasma, the plasma accelerates in the electric field hitting the target 303, and sputters a large number of target atoms; the target atoms are deposited on the substrate 301 to form a thin film.

Preferably, the target has a greater thickness in a region corresponding to a higher magnetic field strength; the target has a smaller thickness in a region corresponding to a lower magnetic field strength.

In order to explain the technical solution of the present invention, the following description uses a specific embodiment to explain.

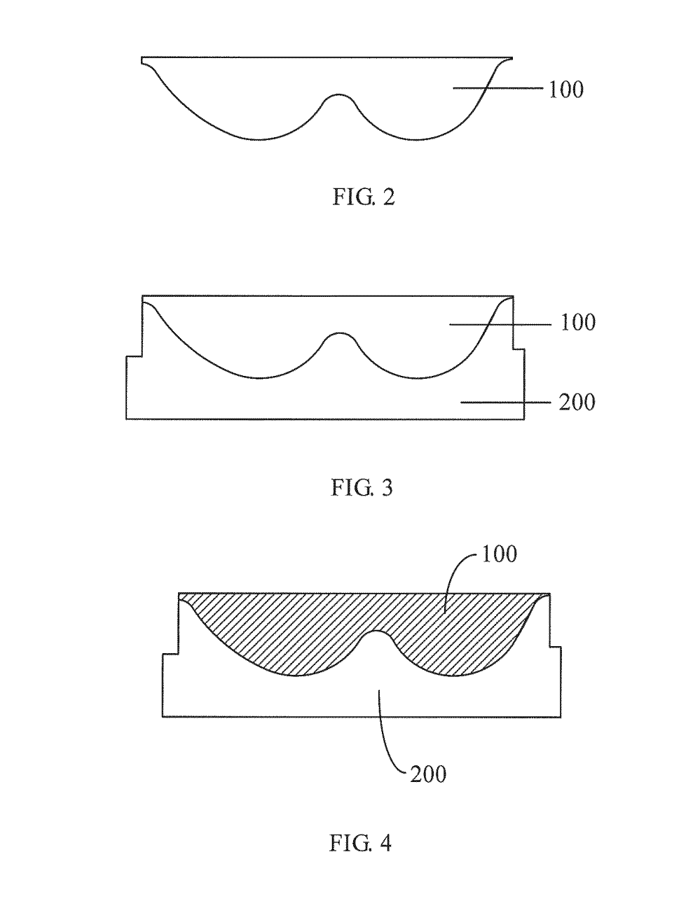

Please refer to FIG. 2, FIG. 3, and FIG. 4. FIG. 2 is a schematic diagram of the target provided by a first embodiment of the present invention. FIG. 3 is a schematic diagram of the target structure before sputtering provided by the first embodiment of the present invention. FIG. 4 is the schematic diagram of the target structure after sputtering provided by the first embodiment of the present invention. In order to explain the instant embodiment conveniently, only a part relative to the present embodiment is illustrated herein.

The vacuum ion sputtering target device comprises: a target 100 and a back plate 200, where the target 100 is located above the back plate 200. The target 100 is used in the vacuum sputtering process, atoms on the surface of the target 100 hit by the plasma are ejected and then accumulated on a substrate surface to form a thin film. The back plate 200 is used for fixing the target 100.

In the present embodiment, when the distribution of the magnetic field strength shows a wavy shape, a lower surface of the target 100 shows the wavy shape, and a peak at the lower surface of the target 100 contacts with the back plate 200. The upper surface of the back plate 200 also shows the wavy shape, and the peak at the lower surface of the target 100 matches to a valley at the upper surface of the back plate 200, so that the target 100 and the back plate 200 are closely combined. In the present embodiment, during the vacuum sputtering process, the wavy shape is formed on the surface of the target 100 hit by the plasma, i.e. the consumed target 100 is the wavy shape. Therefore, the shape of the target is made into the wavy shape so that the target can be used efficiently. Basically, there is no target remaining, so that costs can be reduced.

As a preferred embodiment of the present invention, there are two peaks of the wavy shape structure at the lower surface of the target 100, and two valleys of the wavy shape structure at the upper surface of the back plate 200. Furthermore, the two peaks at the lower surface of the target 100 are embedded respectively into the two valleys at the upper surface of the back plate 200, so that the target and the back plate are closely combined.

As a preferred embodiment of the present invention, the upper surface of the target 100 is a flat plane. This design has an advantage that the thin film formed on the substrate by the ejected material of the target 100 hit by the plasma is more uniform.

As a preferred embodiment of the present invention, the wavy shape at the lower surface of the target 100 is symmetrically disposed. Similarly, the wavy shape at the upper surface of the back plate 200 is also symmetrically disposed. This design has an advantage that the material at two side of the target 100 is consumed at the same time so as to enhance the target utilization but does not leave material at one side of the target 100.

In the present embodiment, the thickness and the size of the target 100 can depend on actual consumption, so that the target 100 can be consumed in one vacuum sputtering process without interruption due to the target 100 not being enough and needing to be exchanged with a new one; the newly exchanged target, which cannot be completely consumed, will not cause a further waste problem. The target quantity according the embodiment of the present invention is set for one time vacuum sputtering operation. Hence, the utilization of the target 100 is efficiently improved so as to reduce costs without wasting materials.

In the present embodiment, the back plate 200 is made of copper. It should be understood that other metal materials can be used as the back plate 200 as well. Under the spirit and principle of the present invention, any modifications, equivalent replacements, and improvements should be included within the claim scope of the present invention.

In the present embodiment, the target 100 can be a metal target, such as: titanium target (Ti), aluminum target (Al), stannum target (Sn), hafnium target (Hf), lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), germanium target (Ge), and so on.

However, it should be understood that the target 100 can also be an alloy target, such as: iron-cobalt target (FeCo), aluminum-silicon target (AlSi), titanium-silicon target (TiSi), chrome-silicon target (CrSi), zinc-aluminum target (ZnAl), titanium-zinc target (TiZn), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), nickel-iron target (NiFe), and so on.

In the embodiment of the present invention, the target 100 is an integrally molded structure, as is the back plate 200. Such a manufacturing method is convenient, which can also save materials at the same time.

An operation principle of the vacuum sputtering is described as follows:

The accommodating space is filled with a small amount of gases, when the voltage between electrodes is very small, only a small amount of ions and electrons exist, and the current density is of the order of magnitude of 10-15 A/cm2. When the voltage between the cathode (i.e., the target 100) and the anode is increased, the charged particles in the electric field are accelerated with the increasing energy, and collide with the electrode or the neutral gas atoms to produce more charged particles until the current reaches the order of magnitude of 10-6 A/cm2. When the voltage is further increased, a negative resistance effect will be generated, which is an “avalanche” phenomenon.

During the time that the ions hit the cathode to generate cathode atoms and secondary electrons, the secondary electrons collide with the neutral atoms to generate more ions, and the ions hit the cathode again and generate more secondary electrons and so forth. When the current density reaches the order of magnitude around 0.01 A/cm2, the current increases with the increasing voltage to form an abnormal glow discharge of high-density plasma, and then the high-energy ions hit the cathode (i.e., the target 100) to produce a sputtering phenomenon. High energy target sputtered particles are deposited on the anode glass (i.e., substrate), so as to achieve the thin film deposition.

Under the bound force of the orthogonal electromagnetic field, the electrons have a spiraling motion when they move to the anode, and are trapped by the vertical electromagnetic field in the vicinity of the target 100, so as to ionize more positive charged ions and electrons.

The magnetron generates the magnetic field; because of the unequal distribution of the magnetic field strength, unequal distribution of the plasma density is generated, a sputtering velocity of the plasma is different and finally the wavy shape is formed at the surface of the target 100. As in the present invention the wavy shape is set for the target, during the vacuum sputtering operation process, the target surface hit by the ions will form the wavy shape, i.e. the consumed target appears in the wavy shape. Therefore, the shape of the target is designed to be the wavy shape and the target utilization is quiet high, basically there is no target remaining, costs are therefore reduced. The target with the wavy shape provided by the embodiment of the present invention can solve the low target utilization problem in the conventional art caused by adopting the rectangular target as a sputtering material.

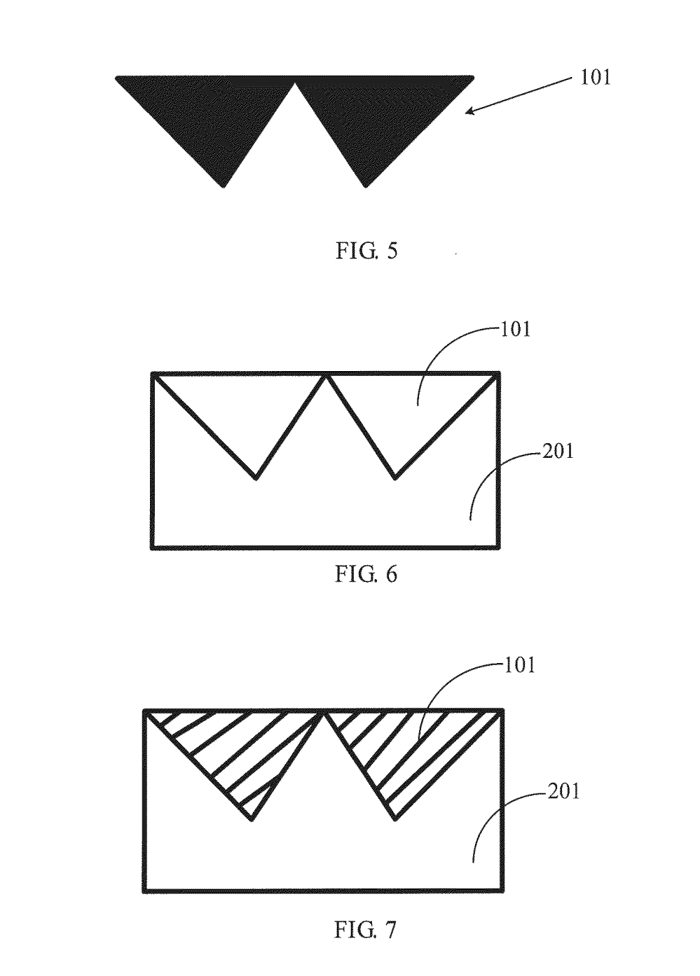

Please refer to FIG. 5, FIG. 6, and FIG. 7. FIG. 5 is the schematic diagram of a target provided by a second embodiment of the present invention; FIG. 6 is the schematic diagram of the target structure before sputtering provided by the second embodiment of the present invention. FIG. 7 is the schematic diagram of the target structure before sputtering provided by the second embodiment of the present invention. In order to explain the instant embodiment conveniently, only a part relative to the present embodiment is illustrated herein.

The vacuum ion sputtering target device comprises: a target 101 and a back plate 201, where the target 100 is located above the back plate 201. The target 101 is used in the vacuum sputtering process, atoms on the surface of the target 101 hit by the plasma are elected and then accumulated on a substrate surface to form a thin film. The back plate 201 is used for fixing the target 101.

In the present embodiment, a lower surface of the target 101 shows a W-shape and an upper surface of the back plate 201 also shows a W-shape, the W-shape of the target 101 matches with the W-shape of the back plate 201 such that the target 101 and the back plate 201 are closely combined. In the present embodiment, during a vacuum sputtering process, a W-shape is formed on the surface of the target 101 hit by the plasma, i.e. the consumed target 101 is the W-shape. Therefore, the shape of the target is made into the W-shape so the target can be used efficiently. Basically, there is no target remaining, so that costs can be reduced.

Furthermore, the W-shape of the target 101 is embedded into the W-shape of the back plate 201 so that the target and the back plate are closely combined. Material at the two side of the W-shape target 101 is consumed at the same time so as to enhance the target utilization but does not leave material at one side of the target 101.

As a preferred embodiment of the present invention, the upper surface of the target 101 is a flat plane. Such the design has an advantage that the thin film formed on the substrate by the ejected material of the target 101 hit by the plasma is more uniform.

However, it should be understood that the upper surface of the target 101 can also be non-planar, such as a rough surface.

In the embodiment of the present invention, the thickness and the size of the target 101 can depend on actual consumption, so that the target 101 can be consumed in one vacuum sputtering process without interruption due to the target 101 being not enough and having to be exchanged with a new one. The newly exchanged target which cannot be completely consumed will not cause a further waste problem. The target quantity according the embodiment of the present invention is set for one time vacuum sputtering operation. Hence, the utilization of the target 100 is efficiently improved so as to reduce costs without wasting materials.

In the present embodiment, the back plate 201 is made of copper. It should be understood that other metal material can be used as the back plate 200 as well. Under the spirit and principle of the present invention, any modifications, equivalent replacements, and improvements should be included within the claim scope of the present invention.

In the instant embodiment, the target 101 can be a metal target, such as: titanium target (Ti), aluminum target (Al), stannum target (Su), hafnium target (Hf), lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), germanium target (Ge), and so on.

However, it should be understood that the target 101 can be an alloy target, such as: iron-cobalt target (FeCo), aluminum-silicon target (AlSi), titanium-silicon target (TiSi), chrome-silicon target (CrSi), zinc-aluminum target (ZnAl), titanium-zinc target (TiZn), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), nickel-iron target (NiFe), and so on.

In the embodiment of the present invention, the target 101 is an integrally molded structure and so is the back plate 201. Such a manufacturing method is convenient and can also save materials at the same time.

An operation principle of the vacuum sputtering is described as follows:

Within the accommodating space filled a small amount of gases, when the voltage between electrodes is very small, only a small amount of ions and electrons exist, and the current density is of the order of magnitude of 10-15 A/cm2. When the voltage between the cathode (i.e., the target 101) and the anode is increased, the charged particles in the electric field are accelerated with the increasing energy, and collide with the electrode or the neutral gas atoms to produce more charged particles until the current reaches the order of magnitude of 10-6 A/cm2. When the voltage is further increased, a negative resistance effect will be generated, which is an “avalanche” phenomenon.

During the time that the ions hit the cathode to generate cathode atoms and secondary electrons, the secondary electrons collide with the neutral atoms to generate more ions, and the ions hit the cathode again and generate more secondary electrons and so forth. When the current density reaches to the order of magnitude around 0.01 A/cm2, the current increases with the increasing voltage to form an abnormal glow discharge of the high-density plasma, and then the high-energy ions hit the cathode (i.e., the target 101) to produce a sputtering phenomenon. High energy target sputtered particles are deposited on the anode glass (i.e., substrate), so as to achieve the thin film deposition.

Under the bound force of the orthogonal electromagnetic field, the electrons move in a spiral motion when they move to the anode, and are trapped by the vertical electromagnetic field in the vicinity of the target 101, so as to ionize more positively charged ions and electrons.

The magnetron generates the magnetic field, because of the unequal distribution of the magnetic field strength, unequal distribution of the plasma density is generated, a sputtering velocity of the plasma is different and finally the wavy shape is formed at the surface of the target 101. As in the present invention the W-shape is set for the target, during the vacuum sputtering operation process, the target surface hit by the ions will form the wavy shape, i.e. the consumed target appears in the W-shape. Therefore, the shape of the target is designed to be the W-shape and the target utilization is quietly high, basically there is no target remaining, costs are therefore reduced. The target with the W-shape provided by the embodiment of the present invention can solve the low target utilization problem in the conventional art caused by adopting the rectangular target as a sputtering material.

In summary, the vacuum ion sputtering target device provided by the present invention where the shape of the target is based on the strength of the magnetic field. For example, the wavy shape is designed as the shape of the target, such as the W-shape. During the vacuum sputtering operation, the surface of the target is hit by the plasma to form the wavy shape, i.e. the consumed target has approximately the wavy shape. Therefore, the shape of the target is designed to be the wavy shape and the target utilization is quiet high. Basically there is no target remaining so costs will be reduced. The target with the wavy shape provided by the embodiment of the present invention can solve the low target utilization problem in the conventional art caused by adopting the rectangular target as a sputtering material.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In particular, with regard to the various functions performed by the above described components, the terms used to describe such components are intended to correspond (unless otherwise indicated) to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

The embodiments were chosen and described in order to explain the principles of the disclosure and their practical application so as to activate others skilled in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A vacuum ion sputtering target device, comprising: an accommodating space provided with a substrate, a magnetron, a target, and a back plate therein, the target being disposed above the back plate, the magnetron being provided below the back plate, the substrate being disposed above the target; wherein a shape of the target depends on a distribution of a magnetic field strength; wherein the target has a greater thickness in a region corresponding to a higher magnetic field strength, the target has a smaller thickness in a region corresponding to a lower magnetic field strength; the target is an integrally molded structure;
wherein during a vacuum sputtering process, the magnetron generates a magnetic field between the target and the substrate, when the accommodating space is provided with plasma, the plasma accelerated in the electric field hits the target, and sputters a large number of target atoms, the target atoms are deposited on the substrate to form a thin film.

2. The vacuum ion sputtering target device as claimed in claim 1, wherein when the distribution of the magnetic field strength shows a wavy shape, a lower surface of the target shows the wavy shape, an upper surface of the back plate shows the wavy shape, and a peak at the lower surface of the target matches to a valley at the upper surface of the back plate, so that the target and the back plate are closely combined.

3. The vacuum ion sputtering target device as claimed in claim 2, wherein the lower surface of the target shows the wavy shape having two peaks, and the upper surface of the back plate shows the wavy shape having two valleys; the two peaks at the lower surface of the target are embedded in the two valleys at the upper surface of the back plate, so that the target and the back plate are closely combined.

4. The vacuum ion sputtering target device as claimed in claim 2, wherein the upper surface of the target is a flat plane.

5. The vacuum ion sputtering target device as claimed in claim 2, wherein the wavy shape at the lower surface of the target is symmetrically disposed.

6. The vacuum ion sputtering target device as claimed in claim 1, wherein the thickness and a size of the target depend on actual consumption.

7. The vacuum ion sputtering target device as claimed in claim 1, wherein the target is a metal target, including: titanium target (Ti), aluminum target (Al), stannum target (Sn), hafnium target (HO, lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), or germanium target (Ge).

8. The vacuum ion sputtering target device as claimed in claim 1, wherein the target is an alloy target, including: iron-cobalt target (FeCo), aluminum-silicon target (AlSi), titanium-silicon target (TiSi), chrome-silicon target (CrSi), zinc-aluminum target (ZnAl), titanium-zinc target (TiZn), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), or nickel-iron target (NiFe).

9. A vacuum ion sputtering target device, comprising: an accommodating space provided with a substrate, a magnetron, a target, and a back plate therein, the target being disposed above the back plate, the magnetron being provided below the back plate, the substrate being disposed above the target; wherein a shape of the target shape depends on a distribution of a magnetic field strength;
wherein during a vacuum sputtering process, the magnetron generates a magnetic field between the target and the substrate, when the accommodating space is provided with plasma, the plasma accelerated in the electric field hits the target, and sputters a large number of target atoms, the target atoms deposited on the substrate to form a thin film.

10. The vacuum ion sputtering target device as claimed in claim 9, wherein the target has a greater thickness in a region corresponding to a higher magnetic field strength, the target has a smaller thickness in a region corresponding to a lower magnetic field strength.

11. The vacuum ion sputtering target device as claimed in claim 9, wherein when the distribution of the magnetic field strength shows a wavy shape, a lower surface of the target shows the wavy shape, an upper surface of the back plate shows the wavy shape, a peak at the lower surface of the target matches to a valley at the upper surface of the back plate, so that the target and the back plate are closely combined.

12. The vacuum ion sputtering target device as claimed in claim 11, wherein the lower surface of the target shows the wavy shape having two peaks, and the upper surface of the back plate shows the wavy shape having two valleys; the two peaks at the lower surface of the target are embedded in the two valleys at the upper surface of the back plate, so that the target and the back plate are closely combined.

13. The vacuum ion sputtering target device as claimed in claim 11, wherein an upper surface of the target is a flat plane.

14. The vacuum ion sputtering target device as claimed in claim 11, wherein the wavy shape at the lower surface of the target is symmetrically disposed.

15. The vacuum ion sputtering target device as claimed in claim 9, wherein the thickness and a size of the target depend on actual consumption.

16. The vacuum ion sputtering target device as claimed in claim 9, wherein the target is a metal target, including: titanium target (Ti), aluminum target (Al), stannum target (Sn), hafnium target (Hf), lead target (Pb), nickel target (Ni), silver target (Ag), selenium target (Se), beryllium target (Be), tellurium target (Te), carbon target (C), vanadium target (V), antimony target (Sb), indium target (In), boron target (B), tungsten target (W), manganese target (Mn), bismuth target (Bi), copper target (Cu), silicon target (Si), tantalum target (Ta), zinc target (Zn), magnesium target (Mg), zirconium target (Zr), chromium target (Cr), stainless steel target (SS), niobium target (Nb), molybdenium target (Mo), cobalt target (Co), iron target (Fe), or germanium target (Ge).

17. The vacuum ion sputtering target device as claimed in claim 9, wherein the target is an alloy target, including: iron-cobalt target (FeCo), aluminum-silicon target (AlSi), titanium-silicon target (TiSi), chrome-silicon target (CrSi), zinc-aluminum target (ZnAl), titanium-zinc target (TiZn), titanium-aluminum target (TiAl), titanium-zirconium target (TiZr), titanium-silicon target (TiSi), nickel-titanium target (TiNi), nickel-chromium target (NiCr), nickel-aluminum target (NiAl), nickel-vanadium target (NiV), or nickel-iron target (NiFe).

18. The vacuum ion sputtering target device as claimed in claim 9, wherein the target is an integrally molded structure.
